(19) United States
(12) Patent Application Publication
(10) Pub. No.: US 2007/0181949 A1
(43) Pub. Date: Aug. 9, 2007

(54) Transistor and novolatile memory device including the same

(76) Inventors: Jung-Dal Choi, Suwon-si (KR); Sang-Hun Jeon, Yongin-si (KR); Young-Kwan Park, Suwon-si (KR); Keun-Ho Lee, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 11/649,368

(22) Filed: Jan. 4, 2007

(30) Foreign Application Priority Data
Jan. 4, 2006 (KR) 2006-01037

(51) Int. Cl. H01L 29/76

(52) U.S. Cl. 257/365

(57) ABSTRACT

A transistor includes a gate electrode on a substrate, source/drain regions in the substrate at both sides of the gate electrode, and a channel region defined between the source/drain regions, wherein the channel region includes a recessed region and at least one of the source/drain regions is spaced away from the recessed region of the channel region.

### BACKGROUND OF THE INVENTION

1. Field of the Invention

The present invention relates to semiconductor devices. More particularly, the present invention relates to a transistor and a nonvolatile memory device including such a transistor.

2. Description of the Related Art

As a gate length of a transistor decreases, an effective channel length becomes shorter, and a threshold voltage of the transistor decreases, thereby aggravating the short channel effect. A recessed channel array transistor (RCAT) in which a channel is disposed at a recessed region in a substrate has been proposed to help overcome the short channel effect.

However, such a RCAT is configured such that an overlapping region between a source/drain diffusion layer and a gate is larger in relation to other transistors, and has a relatively high gate-induced drain leakage (GIDL) current.

A NAND-type nonvolatile memory device usually operates using a self channel boosting mechanism for restraining an inadvertent writing action, i.e., program inhibition function, into a deselected memory cell during a write-in operation. In this condition, if the RCAT is used as a selection transistor of a NAND-type cell string, such a GIDL makes it difficult to retain a proper potential at the channel and thereby causes programming disturbances.

### SUMMARY OF THE INVENTION

The present invention is therefore directed to a transistor and a nonvolatile memory device including such a transistor, which substantially overcomes one or more of the problems due to the limitations and disadvantages of the related art.

It is therefore a feature of an embodiment of the present invention to provide a transistor including a recessed channel architecture that is capable of reducing gate-induced drain leakage.

It is therefore a separate feature of an embodiment of the present invention to provide a nonvolatile memory device including a transistor having a recessed channel architecture that is capable of reducing gate-induced drain leakage.

At least one of the above and other features and advantages of the present invention may be realized by providing a transistor including a gate electrode on a substrate, source/drain regions in the substrate at both sides of the gate electrode, and a channel region defined between the source/drain regions, wherein the channel region includes a recessed region and at least one of the source/drain regions is spaced away from the recessed region of the channel region.

The channel region may include the recessed region and a planar region extending from the recessed region, wherein the planar region may be disposed between the recessed region and the source/drain region spaced away from the recessed region. The source/drain regions may overlap the gate electrode.

One of the source/drain regions may be spaced away from the recessed region while the other of the source/drain regions may contact the recessed region. The channel region may include the recessed region and a planar region extending from a side of the recessed region, the planar region may be disposed between the recessed region and one of the source/drain regions, and the other of the source/drain regions contacts another side of the recessed region.

One of the source/drain regions may be spaced away from the recessed region of the channel region and may overlap with the gate electrode, and the other of the source/drain regions may contact with the recessed region and overlaps with the gate electrode. The source/drain regions at both sides of the gate electrode may be spaced away from the recessed region.

The channel region may include the recessed region and planar regions extending from both sides of the recessed region, the planar regions may be respectively disposed between the recessed region and the source/drain regions. The source/drain regions may overlap with the gate electrode.

At least one of the above and other features and advantages of the present invention may be separately realized by providing a NAND-type nonvolatile memory device including selection transistors and a plurality of memory cell transistors serially connected between the selection transistors, wherein the selection transistor may include a channel region in a substrate including a recessed portion, and a source/drain region shared by the memory cell transistor, wherein the source/drain region shared by the cell transistor is spaced away from the recessed portion.

The selection transistor further may include a gate electrode including a first gate portion and a second gate portion, wherein the second gate portion may extend into a space defined by the recessed portion. The first gate portion may extend on the planar channel portion, and the second gate portion may extend on the recessed channel portion.

The second gate portion may extend a greater distance along a first direction perpendicular to a plane along which the substrate may extend than a distance that the first gate portion may extend along the first direction. The source/drain region shared by the memory cell transistor and the selection transistor may overlap with the gate electrode. The source/drain region shared by the cell transistor and the selection transistor may be spaced away from the recessed portion while another source/drain region of the selection transistor may contact the recessed portion.

The source/drain region shared by the memory cell transistor and the selection transistor may be spaced away from the recessed portion and another source/drain region of the selection transistor may contact the recessed portion. A planar channel portion may be disposed between the recessed portion and the source/drain region shared by the memory cell transistor and the selection transistor. The first gate portion may extend substantially parallel to the substrate and may overlap the source/drain region shared by the memory cell and the selection transistors along a first direction substantially perpendicular to a plane along which the substrate may extend.

The second gate portion may overlap the source/drain region shared by the memory cell and the selection transistor along a second direction substantially parallel to the plane along which the substrate may extend. Each of the memory cell transistors may include a gate electrode on the substrate, and a charge storage layer interposed between the gate electrode and the substrate, wherein the charge storage layer may include at least one of a floating gate, a charge-trapping insulation layer, and a nano-crystalline layer

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a cross-sectional view of a first exemplary embodiment of a non-volatile memory device employing one or more aspects of the invention; and

FIG. 2 illustrates a cross-sectional view of a second exemplary embodiment of a non-volatile memory device employing one or more aspects of the invention.

### DETAILED DESCRIPTION OF THE INVENTION

Korean Patent Application No. 2006-01037 filed on Jan. 4, 2006, in the Korean Intellectual Property Office, and entitled: “Transistor and Nonvolatile Memory Device Including the Same,” is incorporated by reference herein in its entirety.

Aspects of the present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

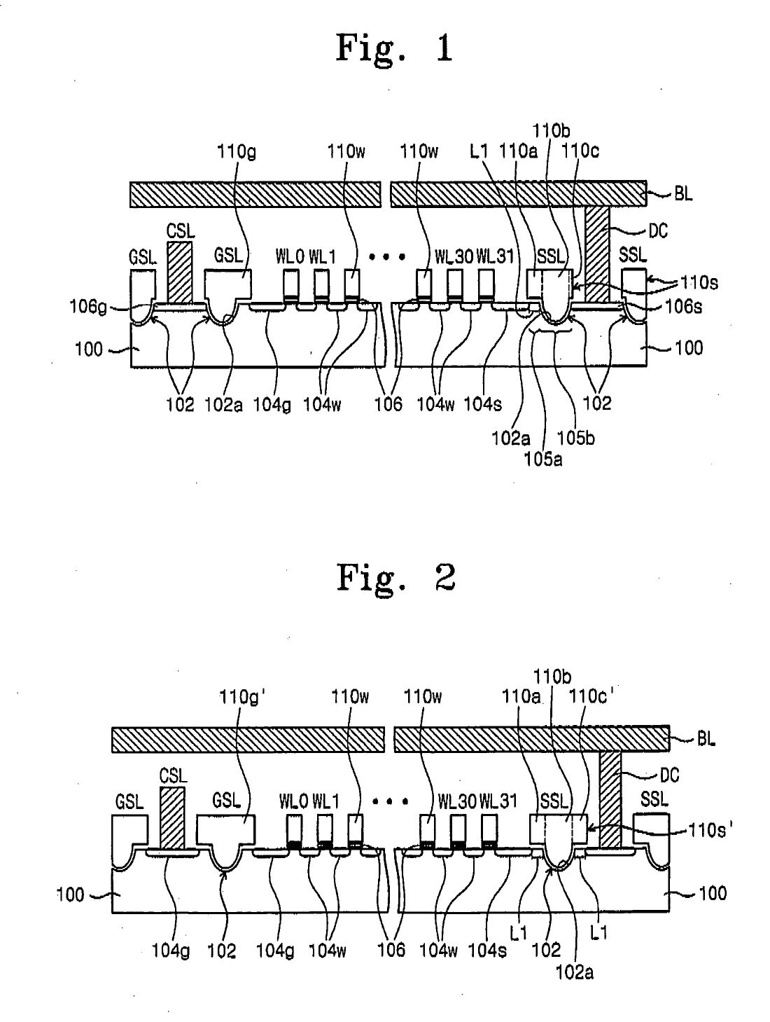

FIG. 1 illustrates a cross-sectional view, taken along a direction in which a bit line extends, of a first exemplary embodiment of a non-volatile memory device employing one or more aspects of the invention.

Referring to FIG. 1, in some embodiments of the invention, selection transistors, e.g., ground selection transistors, string selection transistors, of a NAND-type nonvolatile memory device may include a channel region in a substrate 100. More particularly, the channel region may include a plurality of channel regions, e.g., first channel region 105a and a second channel region 105b, and more particularly, may include, e.g., a planar channel region and a non-planar channel region in the substrate 100. In the exemplary embodiment illustrated, the first channel region 105a may correspond to an exemplary planar channel region and the second channel region 105b may correspond to an exemplary nonplanar channel region. The nonplanar channel region may correspond, e.g., to a recessed region 102 in the substrate 100. Source/drain regions 104s, 106s may be disposed at both sides of a gate electrode 110s of the string selection transistor(s). Source/drain regions 104g, 106g may be disposed at both sides of a gate electrode 110g of the ground selection transistor(s).

The gate electrodes 110s, 110g may include a plurality of gate portions, which may continuously extend from each other, and may correspond to the plurality of channel regions. For example, a non-planar channel region may overlap with a non-planar gate portion, and a planar channel region may overlap with a planar gate portion. In embodiments in which such a non-planar channel region corresponds, e.g., to a recessed region in a substrate, the corresponding non-planar gate portion may extend toward the substrate, and may occupy some or substantially all of a space defined by the nonplanar region, e.g., recessed region.

In the following description, features of the string selection transistor may be employed to describe one or more aspects of the invention. However, aspects of the invention may be employed for other transistors formed on a substrate, e.g., ground selection transistors, and/or, e.g., aspects of the invention may only be applied to ground selection transistors of a device.

The channel region may correspond to a region in the substrate 100 between the source/drain regions 104s and 106s. More particularly, in the exemplary embodiment illustrated in FIG. 1, the substrate 100 includes a non-planar region, e.g., recessed region 102 having a surface 102a, and thus, the channel region may include a first region 105a and a second region 105b. In the following description, a channel including such a recessed region 102 may be called a “recessed channel structure.” Also, as shown in FIG. 1, the gate electrode 110s may include a first gate portion 110a, a second gate portion 110b, and a third gate portion 110c, which together may correspond to a single continuous gate electrode 110s. In the exemplary embodiment illustrated in FIG. 1, the first gate portion 110a corresponds to a planar gate portion, and the second gate portion 110b corresponds to a non-planar gate portion. More particularly, in the exemplary embodiment illustrated in FIG. 1, the planar first gate portion 110a overlaps the planar first channel region 105a, and the non-planar second gate portion 110b overlaps the non-planar second channel region 105b. As shown in FIG. 1, the non-planar second gate portion 110b may protrude toward and have a shape corresponding to a shape of the recessed region 102 of the substrate 100. Embodiments of the invention are not, however, limited to such a structure.

In embodiments of the invention, an interval L1 exists between the source/drain regions 104s and the surface 102a of the recessed region 102. That is, in embodiments of the invention, the surface 102a of the recessed region 102a may not contact and/or correspond to a boundary of the source/drain regions 104s. As shown in FIG. 1, the planar first channel region 105a may be disposed adjacent to the source/drain regions 104s, and may be sandwiched between the source/drain regions 104s and the non-planar second channel region 105b.

The source/drain regions 104s, 106s may be a part of multiple transistors, e.g., the source/drain regions 104s, 106s may be included in both a memory cell transistor and a string selection line transistor. For example, the source/drain regions 104s, 106s may be disposed between a memory cell transistor and a string selection line transistor such that a first side of the source/drain regions 104s, 106s is adjacent to the memory cell transistor and a second side of the source/drain regions 104s, 106s is adjacent to the string selection line transistor. In embodiments of the invention, the source/drain regions 104s, 106s may overlap with the gate electrode 110s along a direction substantially parallel to a direction along which the substrate 100 extends. In some embodiments of the invention, the source/drain regions 104s, 106s may not overlap and/or may minimally overlap the gate electrode 110s along a direction substantially perpendicular to a direction along which the substrate 100 extends.

As illustrated in FIG. 1, in some embodiments of the invention, the string selection transistors and the ground selection transistors may include one source/drain region, e.g., 104s, 104g, that may be spaced apart from the non-planar second region 105b and/or the surface 102a of the recessed region 102, while another source/drain region thereof, e.g., 106s, 106g, may completely abut and/or substantially abut the respective recessed region 102 and/or surface 102a of the substrate 100. More particularly, in such embodiments, e.g., the source/drain regions, e.g., 104s, 104g, that may be shared by a plurality of different types of transistors, e.g., the memory cell transistor and the string selection transistor, may be spaced from the surface 102a of the recessed region 102 by a predetermined interval L1, which the source/drain regions, e.g., 106s, 106g, shared by a plurality of same types of transistors, e.g., adjacent ones of the string selection transistors, may contact the respective sidewall 102s of the respective recessed region 102. More particularly, as shown in FIG. 1, the source/drain region 104s does not contact the sidewall 102a of the recessed region 102, while the source/drain region 106s contacts the respective sidewall 102a of the respective recessed region 102.

Embodiments of the invention provide a transistor including at least one source/drain region that is spaced apart from a nonplanar, e.g., recessed, channel region by a predetermined interval L1, and may thereby provide structures having a significantly lower amount of source/drain region and gate electrode overlap and/or a relatively lower amount of gate-induced drain leakage (GIDL) current as compared to conventional devices including a recessed channel portion. In the exemplary embodiment illustrated in FIG. 1, the source/drain region 106s, 106g shared by adjacent transistors of a same type, e.g., adjacent string selection transistors or adjacent ground selection transistors, extend to and contact the surface 102a of the recessed region 102 of the substrate 100 while source/drain regions 104s, 104g shared by adjacent transistors of a different type, e.g., string selection transistor and adjacent memory cell transistor or ground selection transistor and adjacent memory cell transistor, do not extend to and do not contact the surface 102a of the recessed region 102 of the substrate 100. Embodiments of the invention are not, however, limited to such an arrangement.

In embodiments of the invention, the source/drain regions 104s, 104g shared by the memory cell transistor and the selection transistor may have a lower impurity doping concentration than the source/drain regions, e.g., 106s, 106g, shared by transistors of a same type, e.g., selection transistors.

In the NAND-type nonvolatile memory device according to the first exemplary embodiment of the invention, a selection transistor(s), e.g., ground selection and string selection transistors include a gate electrode and a substrate including respective nonplanar, e.g., protruding or recessed, portions. As illustrated in FIG. 1, ground and string selection lines GSL and SSL may be arranged in parallel with intersecting active fields defined by field isolation films (not shown) in the semiconductor substrate 100. Between the ground and string selection lines GSL and SSL, pluralities of word lines WL0˜WL31 may be arranged to cross over the active fields.

A common source line CSL may be connected to the substrate 100 at, e.g., a region between adjacent ones of the ground selection lines GSL. A bit line contact DC may be connected to the substrate 100 at, e.g., a region between adjacent ones of the string selection lines SSL. Memory cell source/drain regions 104w may be formed in the active fields between the word lines WL0˜WL31. Charge storage layers 106 may be interposed between the active fields and gate electrodes 110w of the memory cell transistors coupled to the word lines WL0˜WL31. More particularly, the memory cell transistor(s) may include a charge storage layer 106 interposed between a gate electrode 110w thereof and the substrate 100. The charge storage layer may include a floating gate layer, a charge-trapping insulation layer, and/or a nano-crystalline layer.

In some embodiments of the invention, as shown in FIG. 1, a gate electrode 110g of the ground selection transistor coupled with the ground selection line GSL, and the gate electrode 110s of the string selection transistor coupled with the ground selection line SSL may be formed on the recessed regions 102 and may be arranged in the active fields. As discussed above, the gate electrodes 110g, 110s may include portions protruding into the recessed region(s) 102 of substrate 100. As discussed above, the gate electrodes, 110g, 110s, may include, e.g., first, second and third portions 110a, 110b, 110c, and the second portion 110b may extend more along a direction substantially perpendicular to a plane along which the substrate 100 extends than the first portion 110a and/or the third portion 110c.

Further, in some embodiments, the gate electrodes 110g and 110s may be laterally asymmetrical structures along, e.g., a plane extending along a direction substantially perpendicular to a plane along which the substrate 100 extends and/or along a direction substantially parallel to a plane along which the substrate 100 extends. As illustrated in FIG. 1, in some embodiments of the invention, the first and third portions 110a, 110c of the gate electrodes 110g, 110s may extend substantially a same distance along a direction in which the bit line extends, while in other embodiments of the invention, the first portions 110a of the gate electrodes 110g, 110s may extend a different, e.g., a greater, distance away from the second portion 110b than the third portion 110c extends away from the second portion 110b. More particularly, the first portion 110a of the gate electrode 110s, 110g may extend substantially a same distance along a direction substantially parallel to a plane along which the substrate 100 extends as the respective predetermined interval L1 corresponding to the space between the respective source/drain region 104s, 104g and the recessed region 102 and more particularly, the surface 102a of the recessed region. In the first exemplary embodiment, the third portion 110c of the gate electrode 110s, 110g may extend a shorter distance along a direction substantially parallel to a plane along which the substrate 100 extends than a distance that the first gate portion 110a extends along the same direction. In some embodiments, the third gate portion 110c may minimally overlap the source/drain region 106g, 106s, and any such minimal overlap between the third portion 110c of the gate electrode 110s, 110g may be a result of processing. In some embodiments, the gate electrodes 110g, 110s including such a third portion 110c may correspond to portions of adjacent gate electrodes 110g, 110s of a same transistor type, e.g., adjacent string selection transistors or adjacent ground selection transistors.

As discussed above, source/drain regions, 104s, 104g, 106s, and 106g, of the selection transistors may each be formed at both sides of the gate electrode 110g of the ground selection transistor and both sides of the gate electrode 110s of the string selection transistor. Among them, the source/drain regions 104g and 104s shared by adjacent memory cell transistors are away from the recessed regions 102 by the predetermined interval L1.

More particularly, channel regions of the selection transistors, e.g., ground selection transistors and string selection transistors, may be formed at respective portions of the substrate 100 under and/or directly overlapped by the gate electrodes 110s and 110g of the selection transistors. The channel regions may be confined in the active fields between the source/drain regions of the selection transistors.

As shown in FIG. 1, the recessed regions 102 may be formed in the active fields between the source/drain regions 104g and 106g of the ground selection transistor, and between the source/drain regions 104s and 106s of the string selection transistor. Thus, e.g., the channel region of the ground selection transistor may include the first channel region 105a in the active field region, and the second channel region 105b that corresponds to a region of the substrate 100 around the recessed region 102.

Embodiments of the invention provide transistors and devices including such transistors that include at least one source/drain region that is spaced apart from a nonplanar, e.g., recessed, channel region by a predetermined interval L1, and may thereby result in a significantly lower amount of source/drain region and gate electrode overlap and/or a relatively lower amount of gate-induced drain leakage (GIDL) current as compared to conventional devices including a recessed channel portion

In general, when writing a data bit into a memory cell coupled to an outer-most one of the word lines, e.g., WL0 and WL31, deselected memory cells coupled to a selected word line should be restrained from the write-in operation, i.e., program inhibition. The deselected memory cells may, however, be self-boosted and may raise potentials between the source/drain regions 104s, 104g and the gate electrodes 110s, 110g, and may generate GIDL. Therefore, e.g., considering that during a write-in mode for a memory cell transistor coupled to the first word line WL0, there may be a relatively large potential difference between the source/drain region 104g and the gate electrode 110g of the ground selection transistor to which a ground voltage may be applied relative to the gate electrode 110s of the string selection transistor to which a Vcc voltage is applied, in some embodiments of the invention, overlap between the gate electrode and the source/drain region 104g shared by the ground selection transistor and the memory cell transistor may be reduced or eliminated by, e.g., providing a predetermined interval L1 between the recessed region 102 and the source/drain region 104g. However, embodiments of the invention are not limited to such an application of one or more aspects of the invention to the ground selection transistors and, particularly the source/drain regions 104s shared by the ground selections transistors and the adjacent memory cell. That is, one or more aspects of the invention may be applied to one, some or all types of transistors in a semiconductor device.

FIG. 2 illustrates a cross-sectional view, taken along the direction in which the bit line extends, of a second exemplary embodiment of a non-volatile memory device employing one or more aspects of the invention.

Referring to FIG. 2, selection transistors, e.g., ground selection transistors and string selection transistors, of a NAND-type nonvolatile memory device according to the second exemplary embodiment, may include a recessed channel structure(s). Only differences between the first and second exemplary embodiments will be described below.

Like the first exemplary embodiment illustrated in FIG. 1, in the second exemplary embodiment, the transistors may include a recessed channel structure. In the following description, a string selection transistor may be used to explain one or more aspects of the invention. However, embodiments of the invention may be applied to, e.g., other types of transistors.

In the second exemplary embodiment, a gate electrode 110s′ may include the first gate portion 110a, the second gate portion 110b and a third gate portion 110c′. More particularly, in the second exemplary embodiment, the third gate portion 110c′ may be similar to the first gate portion 110a. In such embodiments, the gate electrode 110s′ may be laterally symmetrical along, e.g., a plane extending along a direction substantially perpendicular to a direction along which the substrate 100 extends. However, e.g., in some embodiments, a predetermined interval L1 of the planar channel region on each side of the recessed portion 102 may or may not be the same. Thus, in some embodiments, the gate electrode 110s′ may be laterally symmetrical along, e.g., a plane extending along a direction substantially perpendicular to a direction along which the substrate 100 extends. In embodiments of the invention, the gate electrode 110s′ may be laterally asymmetrical along, e.g., a plane extending along a direction substantially parallel to a direction along which the substrate 100 extends.

In some embodiments of the invention, the channel portion, including the nonplanar and the planar channel portions, of, e.g. one of the selection transistors may be laterally symmetrical along, e.g., a plane extending along a direction substantially perpendicular to a direction along which the substrate 100 extends. That is, e.g., in the exemplary embodiment illustrated in FIG. 2, the channel region may include a plurality of planar channel portions, i.e., one on two opposing sides of the gate electrode 110s′, and a nonplanar, e.g., recessed, portion between the plurality of planar portions.

In the second exemplary embodiment illustrated in FIG. 2, a plurality of, e.g., both or all, the source/drain regions 104s of the transistor may be spaced apart from the surface 102a of the recessed region 102 by the predetermined interval L1. That is, e.g., none of the source drain regions 104s, 106s of string selection transistors and the ground selection transistors may contact the recessed region 102 and/or the surface 102a of the recessed region 102 of the substrate 100.

As discussed above, embodiments of the invention corresponding to the first exemplary embodiment of the invention provide, e.g., a transistor including at least one nonplanar, e.g., recessed, channel portion and a source/drain region that is spaced apart from the nonplanar channel portion and/or a surface thereof by way of another channel portion, e.g., planar channel portion between the source/drain region and the nonplanar channel portion, so as to reduce an amount of overlap between a gate electrode and the source/drain region(s) thereof and/or to reduce GIDL. According to the second exemplary embodiment of the invention, a transistor may be provided that includes at least one nonplanar, e.g., recessed, channel portion and a plurality of source/drain regions that are spaced apart from the nonplanar channel portion and/or a surface thereof by way of other channel portions, e.g., planarity of channel portions between the source/drain regions, so as to reduce an amount of overlap between a gate electrode and each of the source/drain electrodes thereof and/or to reduce GIDL.

A gate electrode 110g′ of the ground selection transistor may be coupled with the ground selection line GSL, and the gate electrode 110s′ of the string selection transistor may be coupled with the ground selection line SSL. The gate electrodes 110g′, 110s′ may be formed to at least partially overlap the respective recessed regions 102 arranged in the active fields.

Source/drain regions 104g of the selection transistors may be formed at both sides of the gate electrode 110g′ of the ground selection transistor(s), and the source/drain regions 104s may be formed at both sides of the gate electrode 110s′ of the string selection transistor(s). That is, e.g., in the second exemplary embodiment, source/drain regions 104s, 106s illustrated in FIG. 1, which abut the recessed portion 102 and, more particularly, the surface 102a of the recessed portion 102 are not provided.

Channel regions of the selection transistors may be formed at respective portions of the substrate 100 under and/or directly overlapped by the gate electrodes 110s′ and 110g′ of the selection transistors. The channel regions may be confined in the active fields between the source/drain regions 104s, 104g of the selection transistors. As shown in FIG. 2, the recessed regions 102 may be disposed in the active fields between the source/drain regions 104g of the ground selection transistor, and between the source/drain regions 104s of the string selection transistor. More particularly, the recessed regions 102 may be disposed in the active fields between the planar channel regions of the respective selection transistor. In the second exemplary embodiment, the source/drain regions 104s and 104g shared by the memory cell transistors are spaced away from the recessed channel region of the respective selection transistor by a predetermined interval L1.

As aforementioned, according to aspects of the invention, a transistor including a recessed channel structure may minimize overlapping portions of a gate electrode and source/drain region(s) of the transistor by spacing at least one of the source/drain regions of the transistor away from the recessed channel region by a predetermined interval. Thus, as the recessed channel region is spaced away from at least one of the source/drain regions charged with a voltage that is substantially different from a voltage applied to the gate electrode, embodiments of the invention enable generation of GIDL to be reduced.

Further, by employing one or more aspects of the invention in, e.g., selection transistors of a highly integrated NAND-type nonvolatile memory device, it is possible to restrain generation of GIDL and enhance self-boosting efficiency. Embodiments of the invention provide a highly integrated NAND-type nonvolatile memory device with an improved characteristic for program inhibition.

In general, one or more aspects of the invention provide a transistor, which may occupy a relatively small area on a substrate and may have a structural design, e.g., a recessed portion, to reduce a short channel effect, that has a relatively lower amount of overlap between a gate electrode and source/drain regions thereof, so as to reduce GIDL.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A transistor, comprising:
a gate electrode on a substrate;
source/drain regions in the substrate at both sides of the gate electrode; and
a channel region defined between the source/drain regions,
wherein the channel region includes a recessed region and at least one of the source/drain regions is spaced away from the recessed region of the channel region.

2. The transistor as claimed in claim 1, wherein the channel region comprises the recessed region and a planar region extending from the recessed region, the planar region being disposed between the recessed region and the source/drain region spaced away from the recessed region.

3. The transistor as claimed in claim 1, wherein the source/drain regions overlap the gate electrode.

4. The transistor as claimed in claim 1, wherein one of the source/drain regions is spaced away from the recessed region while the other of the source/drain regions contacts the recessed region.

5. The transistor as claimed in claim 4, wherein:
the channel region includes the recessed region and a planar region extending from a side of the recessed region,
the planar region is disposed between the recessed region and one of the source/drain regions, and
the other of the source/drain regions contacts another side of the recessed region.

6. The transistor as claimed in claim 4, wherein:
one of the source/drain regions is spaced away from the recessed region of the channel region and overlaps with the gate electrode, and
the other of the source/drain regions contacts with the recessed region and overlaps with the gate electrode.

7. The transistor as claimed in claim 1, wherein the source/drain regions at both sides of the gate electrode are spaced away from the recessed region.

8. The transistor as claimed in claim 7, wherein the channel region includes the recessed region and planar regions extending from both sides of the recessed region, the planar regions being respectively disposed between the recessed region and the source/drain regions.

9. The transistor as claimed in claim 7, wherein the source/drain regions overlap with the gate electrode.

10. A NAND-type nonvolatile memory device including selection transistors and a plurality of memory cell transistors serially connected between the selection transistors, wherein the selection transistor, comprises:
a channel region in a substrate including a recessed portion; and
a source/drain region shared by the memory cell transistor,
wherein the source/drain region shared by the cell transistor is spaced away from the recessed portion.

11. The NAND-type nonvolatile memory device as claimed in claim 10, wherein the selection transistor further includes a gate electrode including a first gate portion and a second gate portion, the second gate portion extending into a space defined by the recessed portion.

12. The NAND-type nonvolatile memory device as claimed in claim 11, wherein the first gate portion extends on the planar channel portion and the second gate portion extends on the recessed channel portion.

13. The NAND-type nonvolatile memory device as claimed in claim 11, wherein the second gate portion extends a greater distance along a first direction perpendicular to a plane along which the substrate extends than a distance that the first gate portion extends along the first direction.

14. The NAND-type nonvolatile memory device as claimed in claim 11, wherein the source/drain region shared by the memory cell transistor and the selection transistor overlaps with the gate electrode.

15. The NAND-type nonvolatile memory device as claimed in claim 11, wherein the source/drain region shared by the memory cell transistor and the selection transistor is spaced away from the recessed portion while another source/drain region of the selection transistor contacts the recessed portion.

16. The NAND-type nonvolatile memory device as claimed in claim 15, wherein the source/drain region shared by the cell transistor and the selection transistor is spaced away from the recessed portion while another source/drain region of the selection transistor contacts the recessed portion.

17. The NAND-type nonvolatile memory device as claimed in claim 10, wherein a planar channel portion is disposed between the recessed portion and the source/drain region shared by the memory cell transistor and the selection transistor.

18. The NAND-type nonvolatile memory device as claimed in claim 17, wherein the first gate portion extends substantially parallel to the substrate and overlaps the source/drain region shared by the memory cell and the selection transistors along a first direction substantially perpendicular to a plane along which the substrate extends.

19. The NAND-type nonvolatile memory device as claimed in claim 18, wherein the second gate portion overlaps the source/drain region shared by the memory cell and the selection transistors along a second direction substantially parallel to the plane along which the substrate extends.

20. The NAND-type nonvolatile memory device as claimed in claim 10, wherein each of the memory cell transistors comprise:
a gate electrode on the substrate; and
a charge storage layer interposed between the gate electrode and the substrate,
wherein the charge storage layer includes at least one of a floating gate, a charge-trapping insulation layer, and a nano-crystalline layer.
